(19) United States
(12) Patent Application Publication
(10) Pub. No.: US 2026/0018534 A1
(43) Pub. Date: Jan. 15, 2026

(54) SEMICONDUCTOR PACKAGE

(71) Applicant: Samsung Electronics Co., Ltd., Suwon-si (KR)

(72) Inventors: Soomin YOON, Suwon-si (KR); Young Kun JEE, Suwon-si (KR)

(21) Appl. No.: 19/006,376

(22) Filed: Dec. 31, 2024

(30) Foreign Application Priority Data
Jul. 10, 2024 (KR) 10-2024-0091315

(51) Int. Cl. H01L 23/00; H01L 25/16; H10B 80/00; H10D 80/30

(52) U.S. Cl. CPC H01L 23/562; H01L 24/08; H01L 25/16; H01L 24/16; H01L 24/32; H01L 24/73; H01L 24/80; H01L 24/97; H01L 2224/08145; H01L 2224/16225; H01L 2224/32225; H01L 2224/73204; H01L 2224/80895; H01L 2224/80896; H01L 2224/97; H01L 2924/1431; H10B 80/00; H10D 80/30

(57) ABSTRACT

A semiconductor package may include a substrate including a plurality of vias and a chip stack on the substrate. The chip stack may include a plurality of semiconductor chips, wherein a first semiconductor chip is a lowermost one of the plurality of semiconductor chips in the chip stack, chip pads of the first semiconductor and substrate pads of the substrate are bonded to each other, and the chip pads and the substrate pads are integrally formed of the same metal material, the first semiconductor chip includes a corner region adjacent to a corner of the first semiconductor chip, and a center region excluding the corner region, the substrate includes a trench on an upper surface of the substrate, and the trench extends along a boundary between the corner region and the center region of the first semiconductor chip.

### CROSS-REFERENCE TO RELATED APPLICATION

This U.S. non-provisional patent application claims priority under 35 U.S.C. § 119 to Korean Patent Application No. 10-2024-0091315, filed Jul. 10, 2024, in the Korean Intellectual Property Office, the entire contents of which are hereby incorporated by reference.

### FIELD

The inventive concept relates to a semiconductor package and a method of manufacturing the same, and more particularly, relates to a stacked semiconductor package in which a plurality of semiconductor chips are stacked on a substrate and a method of manufacturing the same.

### BACKGROUND

With the development of the electronic industry, electronic products have increasingly demanded for high performance, high speed, and compact size. In response to this trend, recent packaging technology has processing toward mounting a plurality of semiconductor chips in a single package.

Recently, a demand for portable devices has rapidly increased in the electronic product market. As a result, it is necessary to downscale and reduce a weight of electronic components mounted in portable devices. To realize the miniaturization and lightening of the electronic components, technologies for integrating a plurality of individual elements in a single package, as well as technologies for reducing the sizes of individual mounted components are desirable. Here, various problems may occur as the number of elements to be stacked increases.

### SUMMARY

In some embodiments, a semiconductor package with improved structural stability and a method of manufacturing the same may be provided.

In some embodiments, a method of manufacturing a semiconductor package with a low or reduced occurrence of defects and a semiconductor package manufactured through the same may be provided.

A semiconductor package according to some embodiments of the inventive concept may include a substrate including a plurality of vias and a chip stack on the substrate. The chip stack may include a plurality of semiconductor chips, wherein a first semiconductor chip is a lowermost one of the plurality of semiconductor chips in the chip stack, chip pads of the first semiconductor chip and substrate pads of the substrate are bonded to each other, and the chip pads and the substrate pads are integrally formed of the same metal material, the first semiconductor chip includes a corner region adjacent to a corner of the first semiconductor chip, and a center region excluding the corner region, the substrate includes a trench on an upper surface of the substrate, and the trench extends along a boundary between the corner region and the center region of the first semiconductor chip.

A semiconductor package according to some embodiments of the inventive concept may include a buffer semiconductor chip, a first semiconductor chip on the buffer semiconductor chip, a lower surface of the first semiconductor chip in contact with an upper surface of the buffer semiconductor chip, a second semiconductor chip on the first semiconductor chip, a lower surface of the second semiconductor chip in contact with an upper surface of the first semiconductor chip, and a buffer structure between the buffer semiconductor chip and the first semiconductor chip, wherein the first semiconductor chip has a first side surface and a second side surface in contact with each other, and the buffer structure extends across the first side surface and the second side surface.

A semiconductor package according to some embodiments of the inventive concept may include a semiconductor substrate including a plurality of vias, a plurality of semiconductor chips stacked on the semiconductor substrate, and a molding layer on the semiconductor chips on the semiconductor substrate, wherein the semiconductor substrate further includes a trench on an upper surface of the semiconductor substrate and a buffer structure in the trench, the trench extends across a first side surface and a second side surface of the lowermost semiconductor chip among the semiconductor chips, a distance between the trench and a corner where the first side surface and the second side surface of the lowermost semiconductor chip intersect is 0.1 to 0.25 times a width of the first semiconductor chip, and a rigidity of the buffer structure is smaller than a rigidity of the semiconductor substrate.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view illustrating a semiconductor package according to some embodiments of the inventive concept.

FIGS. 2 to 4 are enlarged views illustrating region ‘A’ of FIG. 1.

FIG. 5 is a plan view illustrating a semiconductor package according to some embodiments of the inventive concept.

FIGS. 6 to 11 are enlarged views illustrating region ‘B’ of FIG. 5.

FIG. 12 is an enlarged view illustrating region ‘A’ of FIG. 1.

FIG. 13 is a cross-sectional view illustrating a semiconductor module according to some embodiments of the inventive concept.

FIGS. 14 to 20 are drawings for illustrating a method of manufacturing a semiconductor package according to some embodiments of the inventive concept.

### DETAILED DESCRIPTION

A semiconductor package according to the inventive concept is described with reference to drawings.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “on” as used herein, may not refer to complete surrounding or covering of the described elements or layers but may, for example, refer to partially surrounding or covering the described elements or layers.

Spatially relative terms such as ‘on,’ ‘above,’ ‘upper,’ ‘lower,’ ‘side,’ and the like may be used herein to describe elements or features with reference to the drawings. However, it will be understood that such spatially relative terms are intended to encompass different orientations of the device in use or operation in addition to the orientation depicted in the figures. For example, if the device in the figures is turned over, elements described as on other elements or features would then be oriented below or lower than the other elements or features.

Components or layers described with reference to being “stacked,” may be arranged in vertical or axial alignment, where each layer or component is directly or indirectly aligned with the previous one in a vertical direction or along a particular axis.

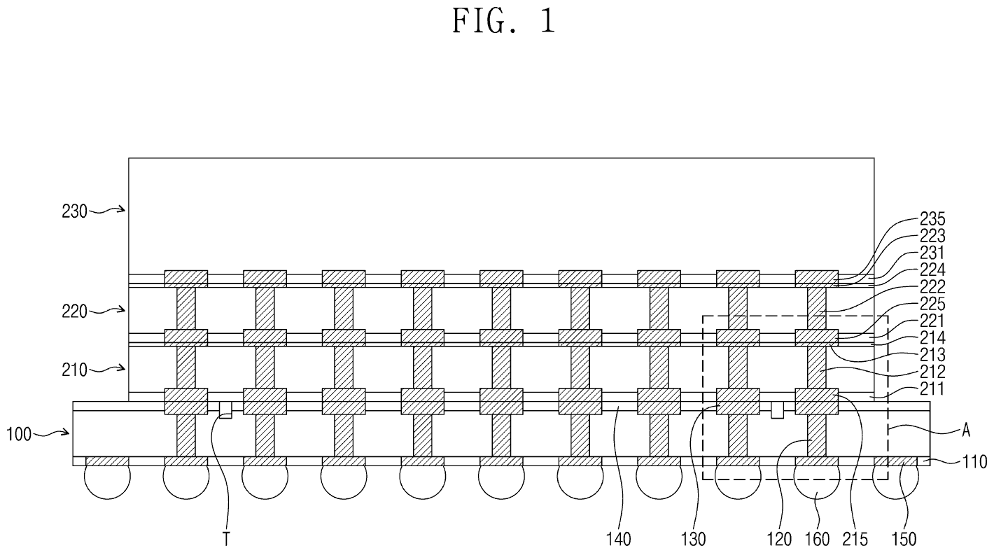

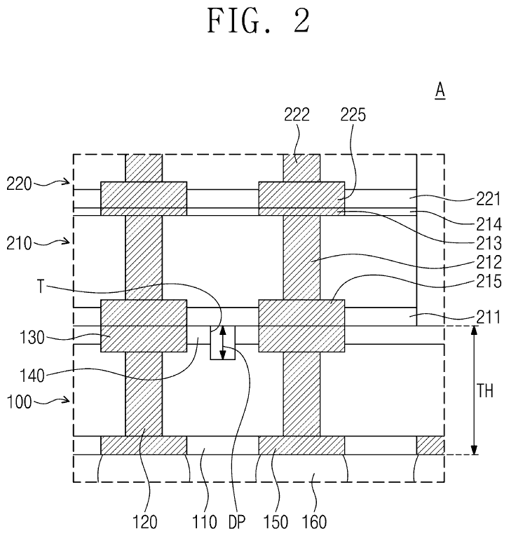

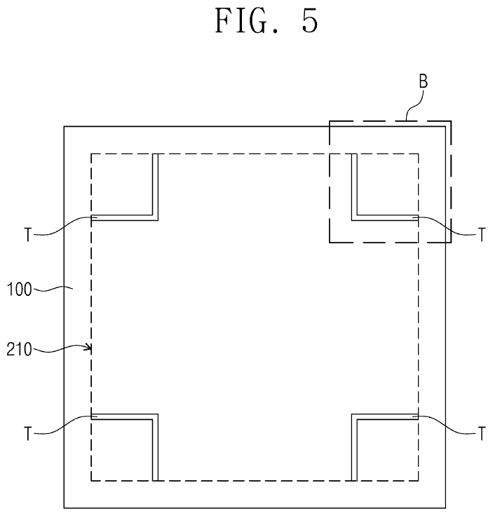

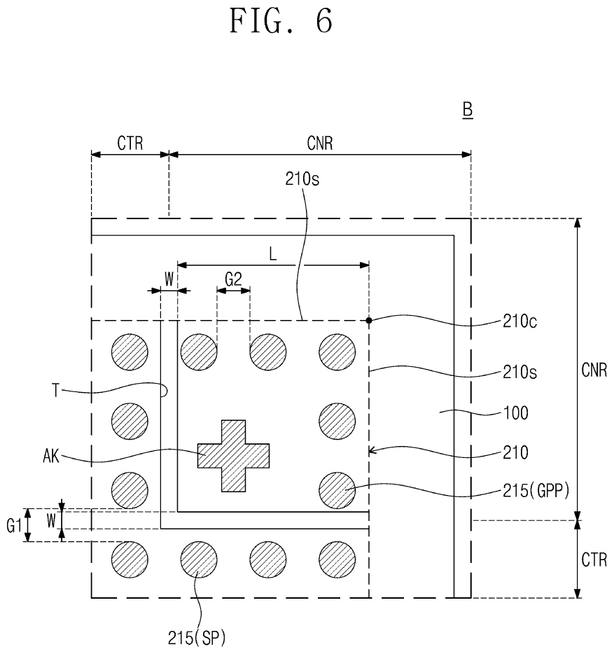

FIG. 1 is a cross-sectional view illustrating a semiconductor package according to some embodiments of the inventive concept. FIGS. 2 to 4 are enlarged views illustrating region ‘A’ of FIG. 1. FIG. 5 is a plan view illustrating a semiconductor package according to some embodiments of the inventive concept. FIGS. 6 to 11 are enlarged views illustrating region ‘B’ of FIG. 5.

A semiconductor package according to some embodiments of the inventive concept may be a stacked package using vias. For example, semiconductor chips of the same type may be stacked on a base substrate, and the semiconductor chips may be electrically connected to each other through vias penetrating the semiconductor chips. The semiconductor chips may be connected to each other using chip terminals provided on lower surfaces thereof.

Referring to FIGS. 1 and 2, a base substrate, such as a buffer semiconductor chip 100, may be provided. The base substrate may be a semiconductor substrate. The base substrate may include an integrated circuit therein. In detail, the base substrate may be a buffer semiconductor chip 100 including an electronic element such as a transistor. For example, the base substrate may be a wafer level die formed of a semiconductor such as silicon (Si). Although FIG. 1 illustrates that the base substrate is a buffer semiconductor chip 100, the inventive concept is not limited thereto. According to some embodiments of the inventive concept, the base substrate may be a substrate that does not include an electronic element such as a transistor, for example, a printed circuit board (PCB). A silicon wafer may have a thinner thickness than a printed circuit board (PCB). Hereinafter, the base substrate and the buffer semiconductor chip 100 will be described as the same component.

The buffer semiconductor chip 100 may include a first circuit layer 110, a first via 120, a first backside pad 130, a first protective layer 140, and a first frontside pad 150.

The first circuit layer 110 may be provided on a lower surface of the buffer semiconductor chip 100. The first circuit layer 110 may include the above-described integrated circuit. For example, the first circuit layer 110 may be a memory circuit, a logic circuit, or a combination thereof. That is, the lower surface of the buffer semiconductor chip 100 may be an active surface. The first circuit layer 110 may include electronic elements such as transistors, an insulating pattern, and a wiring pattern.

The first via 120 may vertically penetrate the buffer semiconductor chip 100. For example, the first via 120 may connect an upper surface of the buffer semiconductor chip 100 and the first circuit layer 110. The first via 120 and the first circuit layer 110 may be electrically connected. The first via 120 may be provided in the plural; that is, a plurality of vias 120 may be provided. If necessary, an insulating layer (not shown) around or surrounding the first via 120 may be provided. For example, the insulating layer (not shown) may include at least one of silicon oxide (SiO), silicon nitride (SiN), silicon oxynitride (SiON), or a low-k dielectric layer.

The first backside pad 130 may be on the upper surface of the buffer semiconductor chip 100. The first backside pad 130 may be connected to the first via 120. The first backside pad 130 may be provided in the plural; that is, a plurality of backside pads 130 may be provided. In this case, the first backside pads 130 may be connected to a plurality of first vias 120, respectively, and an arrangement of the first backside pads 130 may correspond an arrangement of the first vias 120. The first backside pad 130 may be connected to the first circuit layer 110 through the first via 120. The first backside pad 130 may include various metal materials, such as copper (Cu), aluminum (Al), and/or nickel (Ni).

The first protective layer 140 may be on the upper surface of the buffer semiconductor chip 100 to surround the first backside pad 130. The first protective layer 140 may expose the first backside pad 130. An upper surface of the first protective layer 140 may be substantially flat or coplanar with an upper surface of the first backside pad 130. The buffer semiconductor chip 100 may be protected by the first protective layer 140. The first protective layer 140 may include silicon oxide (SiO), silicon nitride (SiN), silicon oxynitride (SiON), or silicon carbonitride (SiCN).

FIGS. 1 and 2 illustrate the first backside pad 130 vertically penetrates the first protective layer 140 to extend into the semiconductor layer of the buffer semiconductor chip 100 therebelow, but the inventive concept is not limited thereto. A lower surface of the first backside pad 130 may be positioned at the same level as a lower surface of the first protective layer 140. Hereinafter, the description will continue based on the embodiments of FIGS. 1 and 2.

The first frontside pad 150 may be on the lower surface of the buffer semiconductor chip 100. In detail, the first frontside pad 150 may be exposed on a lower surface of the first circuit layer 110. A lower surface of the first frontside pad 150 may be substantially flat or coplanar with the lower surface of the first circuit layer 110. The first frontside pad 150 may be electrically connected to the first circuit layer 110. The first frontside pad 150 may be provided in the plural; that is, a plurality of frontside pads 150 may be provided. The first frontside pad 150 may include various metal materials such as copper (Cu), aluminum (Al), and/or nickel (Ni).

Although not illustrated, the buffer semiconductor chip 100 may further include a lower protective layer (not illustrated). The lower protective layer (not shown) may be on the lower surface of the buffer semiconductor chip 100 to cover the first circuit layer 110. The first circuit layer 110 may be protected by the lower protective layer (not shown). The lower protective layer (not shown) may expose the first frontside pad 150. The lower protective layer (not shown) may include silicon oxide (SiO), silicon nitride (SiN), silicon oxynitride (SiON), or silicon carbon nitride (SiCN).

An external terminal 160 may be provided on the lower surface of a buffer semiconductor chip 100. The external terminal 160 may be on the first frontside pad 150. The external terminal 160 may be electrically connected to the first circuit layer 110 and the first via 120. Alternatively, the external terminal 160 may be below the first via 120. In this case, the first via 120 may penetrate the first circuit layer 110 and be exposed on the lower surface of the first circuit layer 110, and the external terminal 160 may be connected to the first via 120. The external terminal 160 may be provided in the plural; that is, a plurality of external terminals 160 may be provided. In this case, the external terminals 160 may be connected to a plurality of first frontside pads 150, respectively. The external terminal 160 may be an alloy including at least one of tin (Sn), silver (Ag), copper (Cu), nickel (Ni), bismuth (Bi), indium (In), antimony (Sb), or cerium (Cc).

The buffer semiconductor chip 100 may have at least one trench T. The configuration of the trench T will be described in more detail together with a lower semiconductor chip 210 described below.

A chip stack may be on the buffer semiconductor chip 100. The chip stack may include a plurality of semiconductor chips 210, 220, and 230. The semiconductor chips 210, 220, and 230 may be semiconductor chips of the same type. For example, the semiconductor chips 210, 220, and 230 may be memory chips. The chip stack may include a lower semiconductor chip 210 connected to a buffer semiconductor chip 100, at least one intermediate semiconductor chip 220 stacked on the lower semiconductor chip 210, and an upper semiconductor chip 230 on the intermediate semiconductor chip 220. The lower semiconductor chip 210, the intermediate semiconductor chip 220, and the upper semiconductor chip 230 may be sequentially stacked on the buffer semiconductor chip 100.

The lower semiconductor chip 210 may have a second circuit layer 211 facing the buffer semiconductor chip 100. The second circuit layer 211 may be provided on a lower surface of the lower semiconductor chip 210. The second circuit layer 211 may include the above-described integrated circuit. For example, the second circuit layer 211 may include a memory circuit. That is, the lower surface of the lower semiconductor chip 210 may be an active surface. The second circuit layer 211 may include electronic elements such as transistors, an insulating pattern, and a wiring pattern.

The lower semiconductor chip 210 may have a second protective layer 214 facing the second circuit layer 211. The second protective layer 214 may be provided on an upper surface of the lower semiconductor chip 210. The second protective layer 214 may protect the lower semiconductor chip 210. The second protective layer 214 may include silicon oxide (SiO), silicon nitride (SiN), silicon oxynitride (SiON), or silicon carbon nitride (SiCN).

The lower semiconductor chip 210 may have a second via 212 penetrating a portion of the lower semiconductor chip 210 in a direction from the second protective layer 214 toward the second circuit layer 211. The second via 212 may be provided in the plural; that is, a plurality of second vias 212 may be provided. An insulating layer (not shown) may be provided to surround the second via 212. For example, the insulating layer (not shown) may include at least one of silicon oxide (SiO), silicon nitride (SiN), silicon oxynitride (SiON), or a low-k dielectric layer. The second via 212 may be electrically connected to the second circuit layer 211.

A second backside pad 213 may be in the second protective layer 214. An upper surface of the second backside pad 213 may be exposed by the second protective layer 214. An upper surface of the second protective layer 214 may be substantially flat or coplanar with the upper surface of the second backside pad 213. The second backside pad 213 may be connected to the second via 212. A second frontside pad 215 may be on the second circuit layer 211. In detail, the second frontside pad 215 may be exposed on a lower surface of the second circuit layer 211. A lower surface of the second frontside pad 215 may be substantially flat or coplanar with the lower surface of the second circuit layer 211. The second frontside pad 215 may be connected to the second circuit layer 211. The second backside pad 213 and the second frontside pad 215 may be electrically connected to the second circuit layer 211 by the second via 212. Each of the second backside pad 213 and the second frontside pad 215 may be provided in the plural; that is, a plurality of second backside pads 213 and second frontside pads 215 may be provided. The second backside pad 213 and the second frontside pad 215 may include various metal materials such as copper (Cu), aluminum (Al), and/or nickel (Ni).

The lower semiconductor chip 210 may be mounted on the buffer semiconductor chip 100. In detail, the lower semiconductor chip 210 may be on the buffer semiconductor chip 100. The lower semiconductor chip 210 may be on the buffer semiconductor chip 100 in a face down manner. The first backside pad 130 of the buffer semiconductor chip 100 and the second frontside pad 215 of the lower semiconductor chip 210 may be vertically aligned. The buffer semiconductor chip 100 and the lower semiconductor chip 210 may come into contact with each other so that the first backside pad 130 and the second frontside pad 215 are connected to each other.

The lower semiconductor chip 210 may be connected to the buffer semiconductor chip 100. In detail, the lower semiconductor chip 210 and the buffer semiconductor chip 100 may be in contact with each other. On an interface between the lower semiconductor chip 210 and the buffer semiconductor chip 100, the first backside pad 130 of the buffer semiconductor chip 100 and the second frontside pad 215 of the lower semiconductor chip 210 may be bonded. In this case, the first backside pad 130 and the second frontside pad 215 may form a metal-to-metal hybrid bonding. In this specification, hybrid bonding means bonding in which two components including the same material are fused at an interface thereof. For example, the first backside pad 130 and the second frontside pad 215 bonded to each other may have a continuous configuration, and an interface between the first backside pad 130 and the second frontside pad 215 may not be visually distinguished. For example, the first backside pad 130 and the second frontside pad 215 may include the same material, and an interface between the first backside pad 130 and the second frontside pad 215 may not be visually distinguished. That is, the first backside pad 130 and the second frontside pad 215 may be provided as one component. For example, the first backside pad 130 and the second frontside pad 215 may be combined with each other to form an integrated body.

On an interface between the buffer semiconductor chip 100 and the lower semiconductor chip 210, the first protective layer 140 of the buffer semiconductor chip 100 and the insulating pattern of the second circuit layer 211 of the lower semiconductor chip 210 may be bonded. In this case, the insulating pattern of the first protective layer 140 and the second circuit layer 211 may form a hybrid bonding of oxide, nitride or oxynitride. For example, the insulating pattern of the first protective layer 140 and the second circuit layer 211 may include the same material, and an interface between the first protective layer 140 and the insulating pattern of the second circuit layer 211 may be not visually distinguished. That is, the first protective layer 140 and the insulating pattern of the second circuit layer 211 may be combined with each other to form an integral body. However, the inventive concept is not limited thereto. The insulating pattern of the first protective layer 140 and the second circuit layer 211 may be composed of different materials, may not have a continuous configuration, and an interface between the first protective layer 140 and the insulating pattern of the second circuit layer 211 may be visually distinguished.

The intermediate semiconductor chip 220 may have substantially the same structure as the lower semiconductor chip 210. For example, the intermediate semiconductor chip 220 may include a third circuit layer 221 facing the buffer semiconductor chip 100, a third protective layer 224 facing the third circuit layer 221, a third via 222 penetrating the intermediate semiconductor chip 220 in a direction from the third protective layer 224 toward the third circuit layer 221, a third backside pad 223 in the third protective layer 224, and a third frontside pad 225 on the third circuit layer 221. The third circuit layer 221 and the third frontside pad 225 may be provided on a lower surface of the intermediate semiconductor chip 220, and the lower surface of the intermediate semiconductor chip 220 may be an active surface. The third protective layer 224 and the third backside pad 223 may be provided on an upper surface of the intermediate semiconductor chip 220.

The upper semiconductor chip 230 may have a structure substantially similar to that of the lower semiconductor chip 210. For example, the upper semiconductor chip 230 may include a fourth circuit layer 231 facing the buffer semiconductor chip 100, and a fourth frontside pad 235 on the fourth circuit layer 231. The upper semiconductor chip 230 may not include a via, a backside pad, and an upper protective layer. However, the inventive concept is not limited thereto. According to some embodiments, the upper semiconductor chip 230 may include at least one of a via, a backside pad, and an upper protective layer. The fourth circuit layer 231 and the fourth frontside pad 235 may be provided on a lower surface of the upper semiconductor chip 230, and the lower surface of the upper semiconductor chip 230 may be an active surface. The upper semiconductor chip 230 may have a thickness thicker than the lower semiconductor chip 210 and the intermediate semiconductor chip 220.

The intermediate semiconductor chip 220 may be mounted on the lower semiconductor chip 210. The second backside pad 213 of the lower semiconductor chip 210 and the third frontside pad 225 of the intermediate semiconductor chip 220 may be vertically aligned. The intermediate semiconductor chip 220 and the lower semiconductor chip 210 may be in contact with each other so that the second backside pad 213 and the third frontside pad 225 are connected to each other.

The upper semiconductor chip 230 may be mounted on the intermediate semiconductor chip 220. The third backside pad 223 of the intermediate semiconductor chip 220 and the fourth frontside pad 235 of the upper semiconductor chip 230 may be aligned vertically. The upper semiconductor chip 230 and the intermediate semiconductor chip 220 may be in contact with each other so that the third backside pad 223 and the fourth frontside pad 235 are connected to each other.

A mounting form of the intermediate semiconductor chips 220 and the upper semiconductor chip 230 may be substantially the same as or similar to a form in which the lower semiconductor chip 210 is mounted on the buffer semiconductor chip 100.

The intermediate semiconductor chip 220 and the lower semiconductor chip 210 may be in contact with each other. On an interface between the intermediate semiconductor chip 220 and the lower semiconductor chip 210, the second backside pad 213 of the lower semiconductor chip 210 and the third frontside pad 225 of the intermediate semiconductor chip 220 may be bonded. In this case, the second backside pad 213 and the third frontside pad 225 may form a hybrid bonding between metals. On an interface between the intermediate semiconductor chip 220 and the lower semiconductor chip 210, the second protective layer 214 of the lower semiconductor chip 210 and the insulating pattern of the third circuit layer 221 of the intermediate semiconductor chip 220 may be bonded. In this case, the second protective layer 214 and the insulating pattern of the third circuit layer 221 may form a hybrid bonding of oxide, nitride, oxynitride, or carbonitride.

The upper semiconductor chip 230 and the intermediate semiconductor chip 220 may come into contact with each other. On an interface between the upper semiconductor chip 230 and the intermediate semiconductor chip 220, the third backside pad 223 of the intermediate semiconductor chip 220 and the fourth frontside pad 235 of the upper semiconductor chip 230 may be bonded. In this case, the third backside pad 223 and the fourth frontside pad 235 may form a hybrid bonding between metals. On an interface between the upper semiconductor chip 230 and the intermediate semiconductor chip 220, the third protective layer 224 of the intermediate semiconductor chip 220 and the insulating pattern of the fourth circuit layer 231 of the upper semiconductor chip 230 may be bonded. In this case, the third protective layer 224 and the insulating pattern of the fourth circuit layer 231 may form a hybrid bonding of oxide, nitride, oxynitride, or carbonitride.

Although FIG. 1 illustrates one intermediate semiconductor chip 220 is provided between the lower semiconductor chip 210 and the upper semiconductor chip 230, but the inventive concept is not limited thereto. According to some embodiments, at least two intermediate semiconductor chips 220 may be provided between the lower semiconductor chip 210 and the upper semiconductor chip 230. In this case, the intermediate semiconductor chips 220 may be bonded to each other in a hybrid bonding manner.

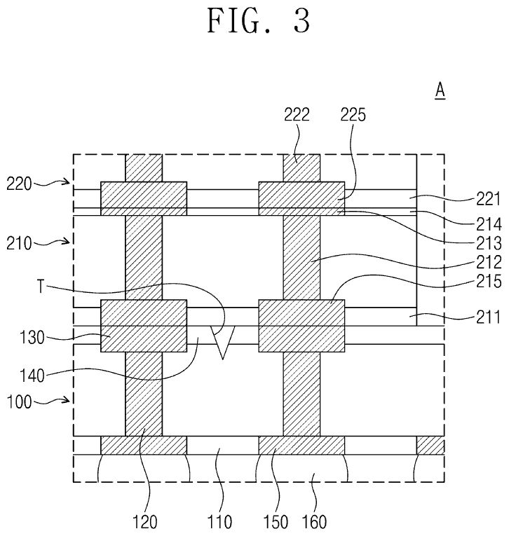

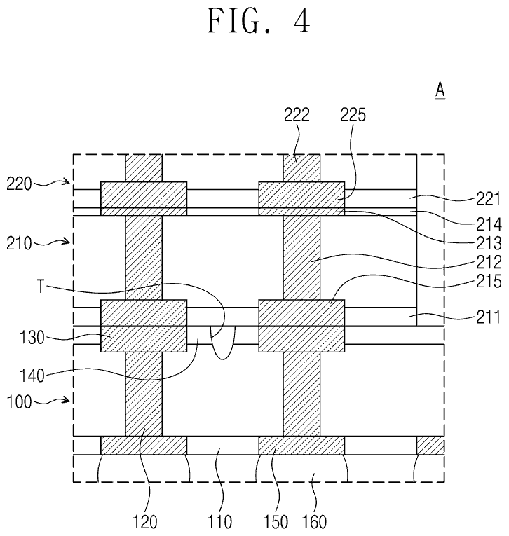

The buffer semiconductor chip 100 may have at least one trench T. The trench T may be provided on the upper surface of the buffer semiconductor chip 100. The trench T may extend from the upper surface of the buffer semiconductor chip 100 toward the lower surface of the buffer semiconductor chip 100. The trench T may vertically penetrate or extend into the first protective layer 140. The trench T may extend toward the inside of the buffer semiconductor chip 100 through the first protective layer 140. In this case, a distance from an upper end of the trench T to a bottom surface of the trench T, i.e., a depth DP of the trench T, may be 0.1 to 0.5 times a thickness TH of the buffer semiconductor chip 100. A cross-section of the trench T may be a square as illustrated in FIG. 2, a downwardly pointed triangle as illustrated in FIG. 3, or a downwardly rounded semicircle as illustrated in FIG. 4. However, the inventive concept is not limited thereto, and the cross-section of the trench T may have various shapes.

As illustrated in FIG. 5, when viewed in a plan view, the trench T may be adjacent to one of corners of the lower semiconductor chip 210. In this case, the corners of the lower semiconductor chip 210 may refer to sides where two adjacent side surfaces of the lower semiconductor chip 210 intersect. In some embodiments, the trench T may be provided in the same number as the corners of the lower semiconductor chip 210, and each of the trenches T may be adjacent to one of the corners of the lower semiconductor chip 210. Hereinafter, with reference to FIG. 6, positions and shapes of the trenches T will be described in more detail based on one trench T.

Referring to FIGS. 5 and 6, one trench T may be adjacent a corner 210c where two side surfaces 210s of a lower semiconductor chip 210 intersect.

The lower semiconductor chip 210 may have a corner region CNR in contact with the corner 210c and a center region CTR excluding the corner region CNR. An integrated circuit of the lower semiconductor chip 210 or signal pads SP connected to the integrated circuit may be in the center region CTR. The corner region CNR may include ground/power pads GPP for providing ground or power to the lower semiconductor chip 210, or an alignment key AK for aligning the lower semiconductor chip 210 on the buffer semiconductor chip 100 during a manufacturing process of a semiconductor package. FIG. 5 illustrates a planar shape of the signal pads SP and the ground/power pads GPP is circular and a planar shape of the alignment key AK is cross-shaped, but the inventive concept is not limited thereto. The buffer semiconductor chip 100 may have signal pads, ground/power pads, and an alignment key corresponding to the signal pads SP, the ground/power pads GPP, and the alignment key AK of the lower semiconductor chip 210. A width of the corner region CNR may be 0.1 to 0.25 times a width of the lower semiconductor chip 210 when measured along the side surfaces 210s of the lower semiconductor chip 210. FIG. 6 illustrates the planar shape of the corner region CNR is rectangular, but the inventive concept is not limited thereto.

The trench T may cross the side surfaces 210s of the lower semiconductor chip 210. When viewed in a plan view, the trench T may extend along a boundary between the corner region CNR and the center region CTR. Each portion of the trench T may have a line shape extending in one direction. Depending on the planar shape of the corner region CNR, the trench T may have an L-shaped planar shape. For example, the trench T may have a first portion and a second portion extending in different directions, respectively, and the first portion and the second portion may be parallel to one of the side surfaces 210s of the lower semiconductor chip 210, respectively. The trench T may be spaced apart from the corner 210c of the lower semiconductor chip 210. A distance L between the trench T and the corner 210c of the lower semiconductor chip 210 may be 0.1 to 0.25 times the width of the lower semiconductor chip 210. For example, a distance L between the trench T and the corner 210c of the lower semiconductor chip 210 may be 0.1 millimeter to 2 millimeters. The trench T may be spaced from the signal pads SP, the ground/power pads GPP, and the alignment key AK. A width W of the trench T may be 0.1 to 0.5 times a distance between two adjacent pads of the buffer semiconductor chip 100 or a distance between two adjacent pads of the lower semiconductor chip 210. For example, the width W of the trench T may be 0.1 to 0.5 times a distance G1 between adjacent signal pads SP or a distance G2 between adjacent ground/power pads GPP. Here, the width W of the trench T may correspond to a distance between inner side surfaces of the trench T when measured in a direction perpendicular to a direction in which the trench T extends when viewed in a plan view. Alternatively, the width W of the trench T may be 0.1 to 0.5 times a spacing between the signal pad SP and the ground/power pad GPP that are adjacent to each other with the trench T therebetween.

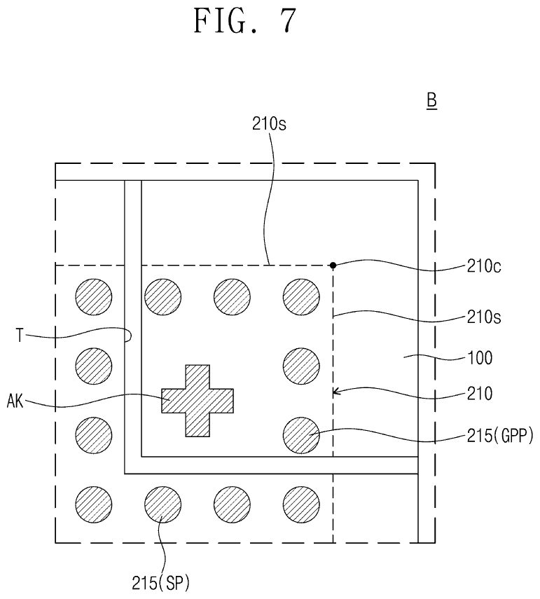

Ends of the trench T may be spaced apart from the side surfaces of the buffer semiconductor chip 100. For example, as illustrated in FIG. 6, the trench T may be in contact with the side surfaces 210s of the lower semiconductor chip 210. The ends of the trench T may be aligned with the side surfaces 210s of the lower semiconductor chip 210. That is, the trench T may be provided below the lower semiconductor chip 210 and may not extend outside the lower semiconductor chip 210 when viewed in a plan view. Alternatively, as illustrated in FIG. 7, the trench T may extend outside the lower semiconductor chip 210. The trench T may be in contact with the side surfaces of the buffer semiconductor chip 100. The ends of the trench T may be aligned with the side surfaces of the buffer semiconductor chip 100.

FIGS. 6 and 7 illustrates a planar shape of the trench T has an L-shape, but the inventive concept is not limited thereto.

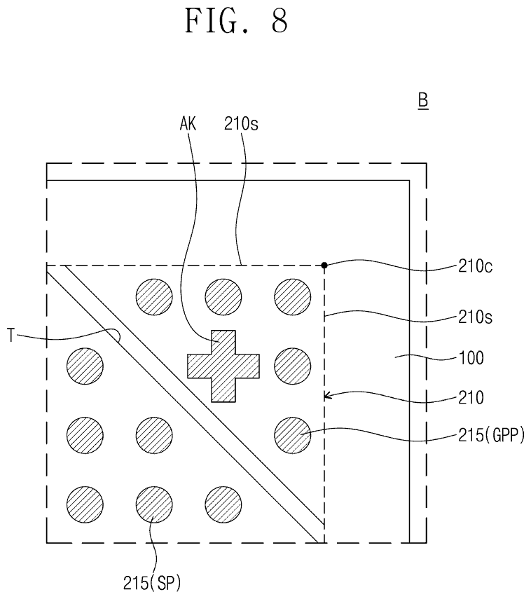

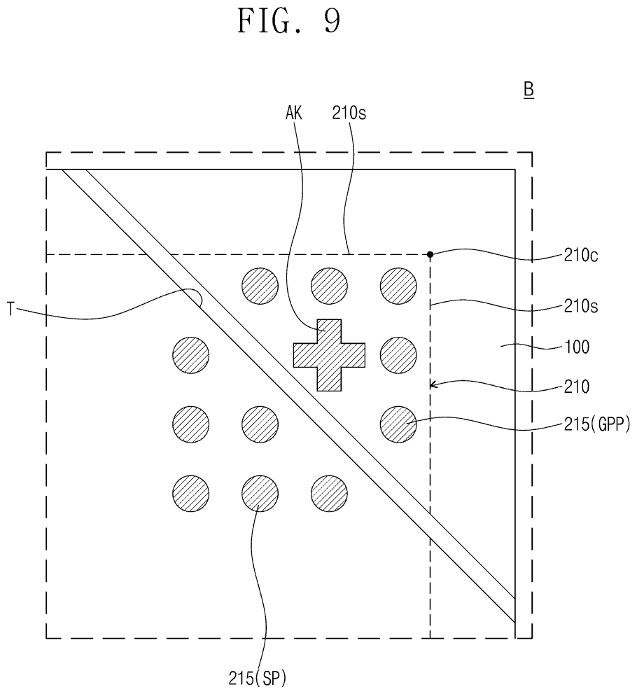

According to some embodiments, as illustrated in FIG. 8, a planar shape of the trench T may have a straight line shape connecting the side surfaces 210s of the lower semiconductor chip 210. For example, when viewed in a plan view, the trench T may extend in one direction, and the one direction in which the trench T extends may intersect the side surfaces 210s of the lower semiconductor chip 210. The ends of the trench T may be spaced apart from the side surfaces of the buffer semiconductor chip 100. For example, as illustrated in FIG. 8, the trench T may be in contact with the side surfaces 210s of the lower semiconductor chip 210. The ends of the trench T may be aligned with the side surfaces 210s of the lower semiconductor chip 210. Alternatively, as illustrated in FIG. 9, the trench T may extend outwardly of the lower semiconductor chip 210 in the one direction. The trench T may be in contact with the side surfaces of the buffer semiconductor chip 100. The ends of the trench T may be aligned with the side surfaces of the buffer semiconductor chip 100.

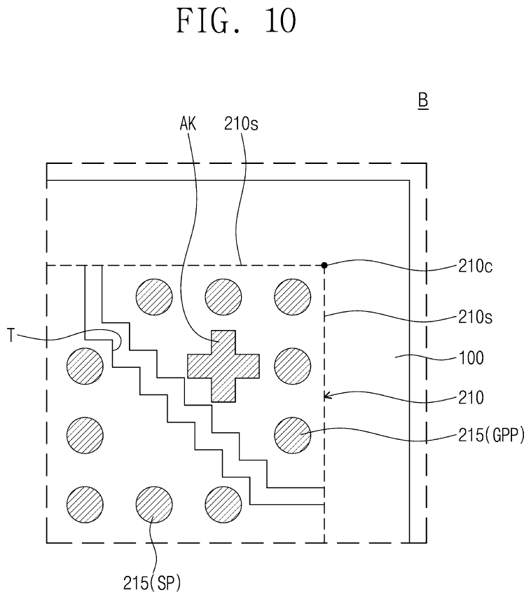

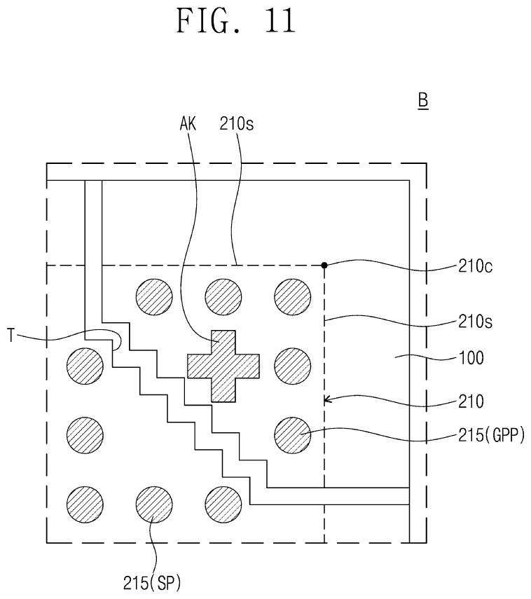

According to some embodiments, as illustrated in FIG. 10, a planar shape of the trench T may have a staircase shape. For example, the trench T may extend from one of the side surfaces 210s of the lower semiconductor chip 210 toward the adjacent other one. The trench T may have third portions and fourth portions extending in different directions, respectively, and the third portions and the fourth portions may be parallel to one of the side surfaces 210s of the lower semiconductor chip 210, respectively. The third portions and the fourth portions may be alternately connected. The end portions of the trench T may be spaced apart from the side surfaces of the buffer semiconductor chip 100. For example, as illustrated in FIG. 10, the trench T may be in contact with side surfaces 210s of the lower semiconductor chip 210. The ends of the trench T may be aligned with the side surfaces 210s of the lower semiconductor chip 210. Alternatively, as illustrated in FIG. 11, the trench T may extend outwardly of the lower semiconductor chip 210 in the one direction. The trench T may be in contact with side surfaces of the buffer semiconductor chip 100. The ends of the trench T may be aligned with the side surfaces of the buffer semiconductor chip 100.

The semiconductor chips 210, 220, and 230 may be vertically stacked on the buffer semiconductor chip 100. In addition, the buffer semiconductor chip 100 and the semiconductor chips 210, 220, and 230 may be bonded to each other. Accordingly, a load may be applied between the semiconductor chips 210, 220, and 230, and in particular, the load applied to the buffer semiconductor chip 100 by the lowermost lower semiconductor chip 210 may be the greatest. In this case, the semiconductor chips 100, 210, 220, and 230 may be bent due to heat generated when the semiconductor package is driven or heat provided in a process of forming the semiconductor package. In particular, a degree of bending of the buffer semiconductor chip 100, which is provided in a different size from the upper semiconductor chips 210, 220, and 230, may be large. The buffer semiconductor chip 100 may be bent, for example, in a crying warpage form. Accordingly, the larger stress applied between the semiconductor chips 210, 220, and 230, the closer to the corner of the buffer semiconductor chip 100 or the corner of the upper semiconductor chips 210, 220, and 230. Accordingly, the stress applied to the buffer semiconductor chip 100 may be greatest at the corner region CNR of the lower semiconductor chip 210 between the buffer semiconductor chip 100 and the lower semiconductor chip 210.

According to some embodiments of the inventive concept, the trench T may be provided on the upper surface of the buffer semiconductor chip 100 below the corner region CNR of the lower semiconductor chip 210. The trench T may suppress warping of the buffer semiconductor chip 100. In particular, the trench T may suppress warping of the buffer semiconductor chip 100 below the corner region CNR of the lower semiconductor chip 210 where the stress is greatest. Accordingly, the stress applied to the buffer semiconductor chip 100 by the chip stack, particularly the lower semiconductor chip 210, may be reduced, and the buffer semiconductor chip 100 may be prevented from being damaged by the stress. That is, a semiconductor package with improved structural stability may be provided.

Although not shown, the semiconductor package may further include a molding layer. The molding layer may cover the upper surface of the buffer semiconductor chip 100. The molding layer may surround the chip stack. That is, the molding layer may cover side surfaces of the lower semiconductor chip 210, the intermediate semiconductor chip 220, and the upper semiconductor chip 230. The molding layer may cover the upper surface of the upper semiconductor chip 230. Alternatively, the molding layer may expose the upper surface of the upper semiconductor chip 230. The molding layer may include an insulating material. For example, the molding layer may include an epoxy molding compound (EMC).

In the following embodiments, for the convenience of explanation, a detailed description of technical features that overlap those described above with reference to FIGS. 1 to 11 will be omitted, and differences will be described in detail. The same reference numerals may be provided for the same configurations as the semiconductor package according to the embodiments of the inventive concept described above.

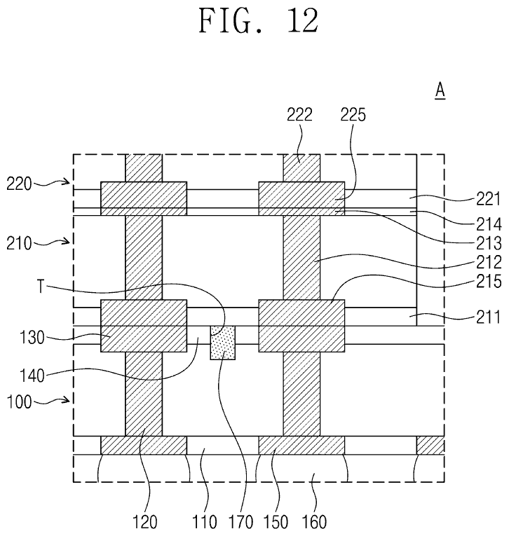

FIG. 12 is an enlarged view of region ‘A’ of FIG. 1.

Referring to FIG. 12, the buffer semiconductor chip 100 may further include a buffer structure 170 provided in the trench T. The buffer structure 170 may completely fill the interior of the trench T. An upper surface of the buffer structure 170 may be substantially flat or coplanar with the upper surface of the buffer semiconductor chip 100, that is, the upper surface of the first protective layer 140. That is, the trench T may be between the buffer semiconductor chip 100 and the lower semiconductor chip 210. The trench T may be buried in an upper portion of the buffer semiconductor chip 100. The trench T may be in contact with the lower surface of the lower semiconductor chip 210.

When the trench T is provided in the plural, the buffer structure 170 may also be provided in the plural, and each of the buffer structures 170 may fill one trench T. The buffer structure 170 may include a material having low rigidity. For example, the rigidity of the buffer structure 170 may be smaller than the rigidity of the semiconductor layer of the buffer semiconductor chip 100. As an example, the buffer structure 170 may include an insulating polymer or air. In some embodiment, when the buffer structure 170 includes air filling the trenches T, the structure may be the same as the embodiments of FIGS. 1 to 11. Alternatively, the buffer structure 170 may include a material having a high strain rate. As an example, the buffer structure 170 may include a metal material.

According to some embodiments of the inventive concept, as the rigidity of the buffer structure 170 is smaller than the rigidity of the buffer semiconductor chip 100, the buffer semiconductor chip 100 may absorb the stress applied to the buffer semiconductor chip 100 when the buffer semiconductor chip 100 is bent. That is, the buffer structure 170 may suppress the bending of the buffer semiconductor chip 100. Accordingly, the stress applied to the buffer semiconductor chip 100 by the chip stack, particularly the lower semiconductor chip 210, may be reduced, and the buffer semiconductor chip 100 may be prevented from being damaged by the stress. That is, a semiconductor package with improved structural stability may be provided.

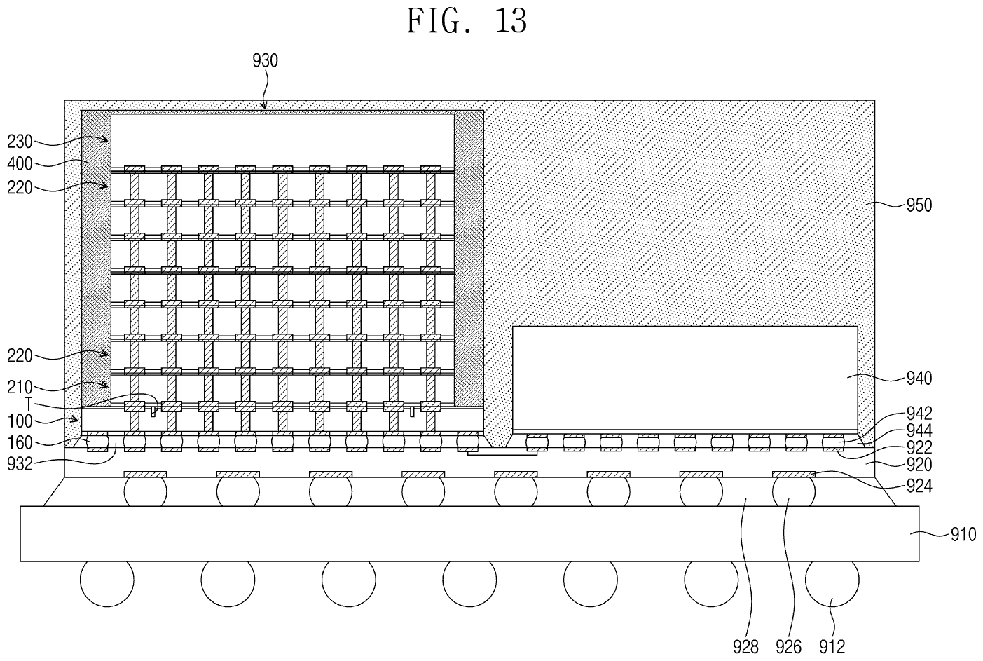

FIG. 13 is a cross-sectional view illustrating a semiconductor module according to some embodiments of the inventive concept.

Referring to FIG. 13, a semiconductor module may be, for example, a memory module including a module substrate 910, a chip stack package 930 mounted on the module substrate 910 and a graphic processing unit (GPU) 940, and an external or outer molding layer 950 covering the chip stack package 930 and the graphic processing unit 940. The semiconductor module may further include an interposer 920 provided on the module substrate 910.

A module substrate 910 may be provided. The module substrate 910 may include a printed circuit board (PCB) having a signal pattern on an upper surface thereof.

Module terminals 912 may be below the module substrate 910. The module substrate 910 may include solder balls or solder bumps, and the semiconductor module may be provided in the form of a ball grid array (BGA), a fine ball-grid array (FBGA), or a land grid array (LGA) depending on a type and an arrangement of the module substrate 910. An interposer 920 may be provided on the module substrate 910.

The interposer 920 may include first substrate pads 922 exposed on an upper surface of the interposer 920, and second substrate pads 924 exposed on a lower surface of the interposer 920. The interposer 920 may redistribute the chip stack package 930 and the graphic processing unit 940. The interposer 920 may be mounted on the module substrate 910 in a flip chip manner. For example, the interposer 920 may be mounted on the module substrate 910 using substrate terminals 926 provided on the second substrate pads 924. The substrate terminals 926 may include solder balls or solder bumps, etc. A first underfill layer 928 may be provided between the module substrate 910 and the interposer 920.

A chip stack package 930 may be on the interposer 920. The chip stack package 930 may have a structure identical to or similar to the semiconductor package described with reference to FIGS. 1 to 12. For example, the chip stack package 930 may include a lower semiconductor chip 210, intermediate semiconductor chips 220, and an upper semiconductor chip 230 stacked on a buffer semiconductor chip 100. The buffer semiconductor chip 100 may have a trench T adjacent to a corner region of the lower semiconductor chip 210. The chip stack package 930 may further include an internal molding layer 400 surrounding the lower semiconductor chip 210, the intermediate semiconductor chips 220, and the upper semiconductor chip 230 on the buffer semiconductor chip 100.

The chip stack package 930 may be mounted on the interposer 920. For example, the chip stack package 930 may be connected to the first substrate pads 922 of the interposer 920 through the external terminals 160 of the buffer semiconductor chip 100. A second underfill layer 932 may be provided between the chip stack package 930 and the interposer 920. The second underfill layer 932 may fill a space between the interposer 920 and the buffer semiconductor chip 100 and surround external terminals 160 of the buffer semiconductor chip 100.

A graphic processing unit 940 may be on the interposer 920. The graphic processing unit 940 may be spaced apart from the chip stack package 930. A thickness of the graphic processing unit 940 may be thicker than a thickness of the semiconductor chips 100 and 200 of the chip stack package 930. The graphic processing unit 940 may include a logic circuit. That is, the graphic processing unit 940 may be a logic chip. Bumps 942 may be provided on a lower surface of the graphic processing unit 940. For example, the graphics processing unit 940 may be connected to the first substrate pads 922 of the interposer 920 through the bumps 942. A third underfill layer 944 may be provided between the interposer 920 and the graphics processing unit 940. The third underfill layer 944 may fill a space between the interposer 920 and the graphics processing unit 940 and may surround the bumps 942.

The outer molding layer 950 may be provided on the interposer 920. The outer molding layer 950 may cover an upper surface of the interposer 920. The outer molding layer 950 may surround the chip stack package 930 and the graphics processing unit 940. An upper surface of the outer molding layer 950 may be positioned at the same level as the upper surface of the chip stack package 930. The outer molding layer 950 may include an insulating material. For example, the outer molding layer 950 may include an epoxy molding compound (EMC).

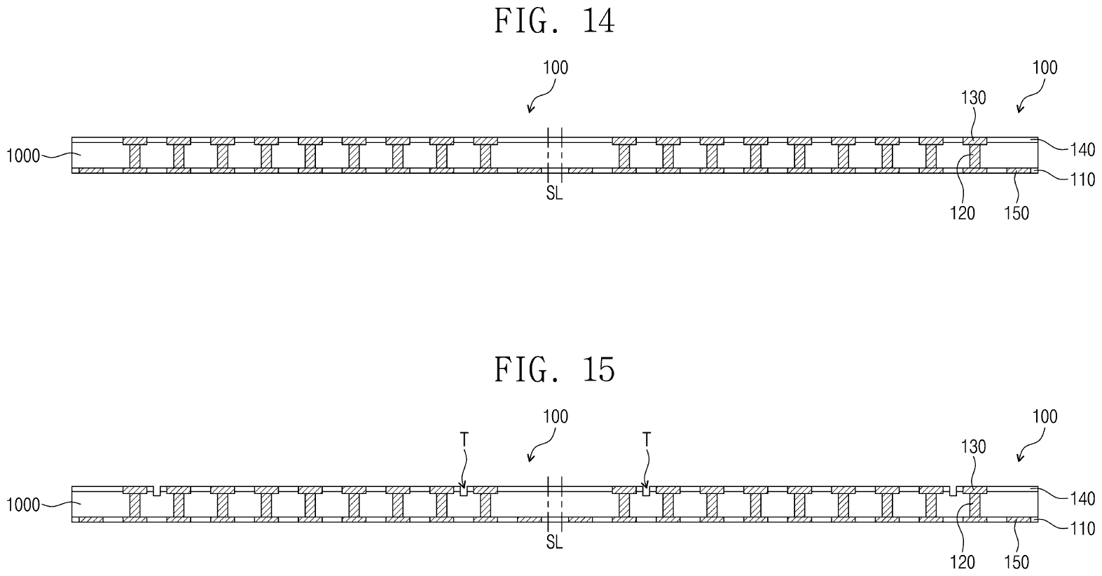

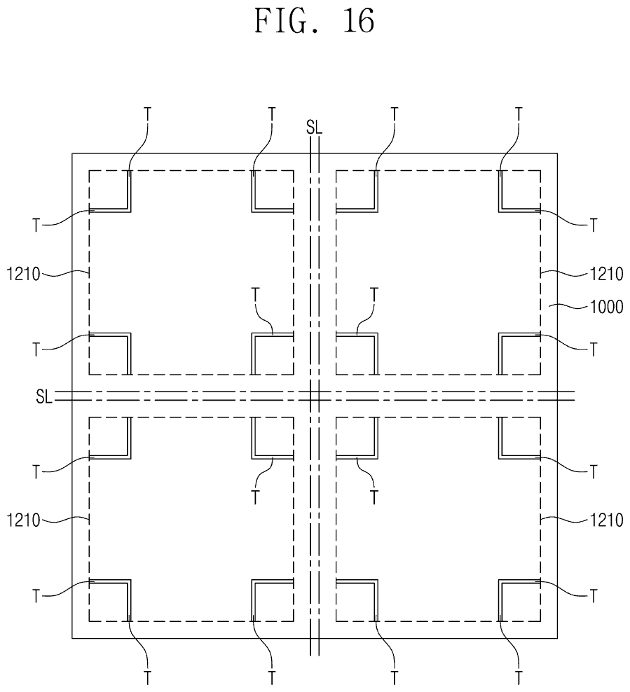

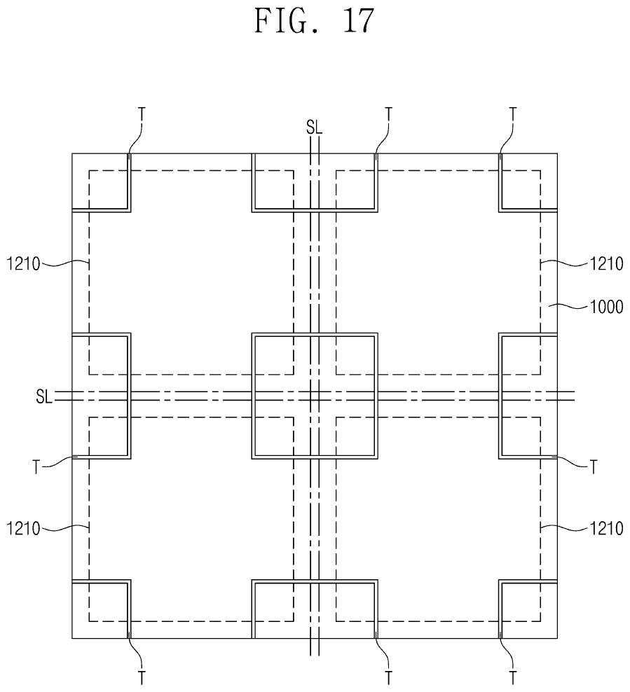

FIGS. 14 to 20 are drawings for illustrating a method of manufacturing a semiconductor package according to some embodiments of the inventive concept. FIGS. 14, 15, and 18 to 20 correspond to cross-sectional views of a semiconductor package during a manufacturing process, and FIGS. 16 and 17 correspond to top views of the semiconductor package of FIG. 15.

Referring to FIG. 14, buffer semiconductor chips 100 may be formed. The buffer semiconductor chips 100 may be substantially the same as or similar to the buffer semiconductor chips 100 described with reference to FIGS. 1 to 12. For example, the buffer semiconductor chips 100 may include a first circuit layer 110 provided on one surface of the buffer semiconductor chips 100, a first protective layer 140 facing the first circuit layer 110, first vias 120 penetrating the buffer semiconductor chips 100 in a direction from the first protective layer 140 toward the first circuit layer 110, first backside pads 130 in the first protective layer 140, and first frontside pads 150 on the first circuit layer 110. In detail, a semiconductor wafer 1000 may be provided. A first circuit layer 110 may be formed by forming a transistor or an integrated circuit, etc. on the frontside surface of a semiconductor wafer 1000, and first frontside pads 150 connected to the first circuit layer 110 may be formed on the first circuit layer 110. After forming through holes on a back surface of the semiconductor wafer 1000, a conductive material may be filled in the through holes to form first vias 120 connected to the first circuit layer 110. The first protective layer 140 covering the first vias 120 may be formed on the back surface of the semiconductor wafer 1000, and first backside pads 130 connected to the first vias 120 may be formed in the first protective layer 140. One side of the semiconductor wafer 1000 on which the first circuit layer 110 is provided may be an active surface, and the opposite side thereof may be an inactive surface. The buffer semiconductor chips 100 may be spaced apart from each other with a scribe lane region SL in which a sawing process is performed in a process described below. That is, the scribe lane region SL may define regions on the semiconductor wafer 1000 where the buffer semiconductor chips 100 are formed.

Although not illustrated, the semiconductor wafer 1000 may be provided on a carrier substrate. The carrier substrate may be an insulating substrate including glass or polymer, or a conductive substrate including metal. An adhesive member may be provided on an upper surface of the carrier substrate. The semiconductor wafer 1000 may be adhered to the carrier substrate such that the first circuit layer 110 faces the carrier substrate.

Referring to FIG. 15, the first protective layer 140 may be patterned to form trenches T. For example, after forming a mask pattern on the first protective layer 140, an etching process may be performed using the mask pattern as an etching mask. During the etching process, the trenches T may penetrate the first protective layer 140 and extend into the semiconductor layer of the buffer semiconductor chips 100. However, the inventive concept is not limited thereto, and the trenches T may not extend into the semiconductor layer of the buffer semiconductor chips 100. The trenches T may be formed on the outer portion of the buffer semiconductor chips 100. In detail, as illustrated in FIG. 16, the semiconductor wafer 1000 may have mounting regions 1210 for mounting lower semiconductor chips on the buffer semiconductor chips 100. The mounting regions 1210 may be regions where the lower semiconductor chips are mounted in the process described below, and may have the same planar shape as the lower semiconductor chips. The trenches T may be formed adjacent to each corner of the mounting regions 1210. For example, the trenches T may connect two sides adjacent to each corner. A planar shape of each of the trenches T may be the same as or similar to that described with reference to FIGS. 6, 8, and 10. Ends of the trenches T may be aligned with the sides of the mounting regions 1210. Alternatively, as illustrated in FIG. 17, the trenches T may extend outside the mounting regions 1210. The trenches T may be connected to other adjacent trenches T across the scribe lane region SL.

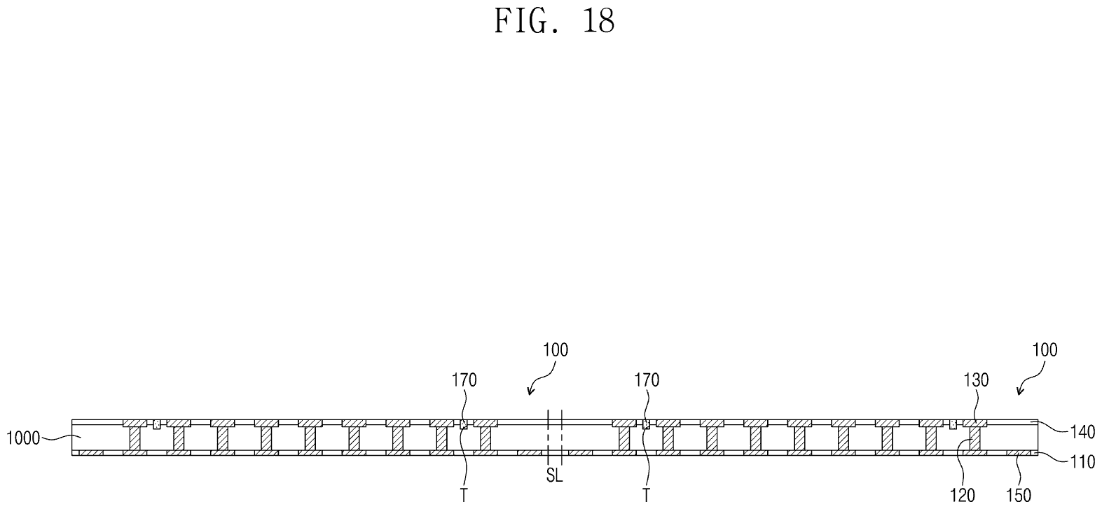

According to some embodiments, as illustrated in FIG. 18, a buffer structure 170 may be formed in the trenches T. For example, an insulating layer may be applied on the first protective layer 140 to fill the inside of the trenches T, and a planarization process may be performed on the insulating layer until an upper surface of the first protective layer 140 is exposed, thereby forming the buffer structure 170. In this case, the semiconductor package described with reference to FIG. 12 may be manufactured. Hereinafter, the description will continue based on the embodiments of FIG. 15.

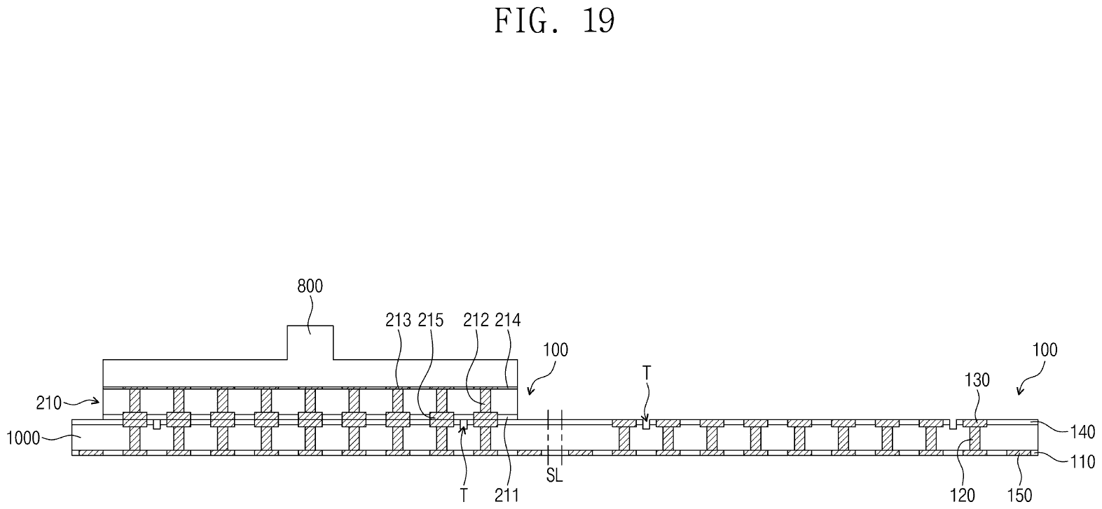

Referring to FIG. 19, a lower semiconductor chip 210 may be manufactured. The lower semiconductor chip 210 may be substantially the same as or similar to the lower semiconductor chip 210 described with reference to FIGS. 1 to 12. For example, the lower semiconductor chip 210 may include a second circuit layer 211 provided on one surface of the lower semiconductor chip 210, a second protective layer 214 facing the second circuit layer 211, a second via 212 penetrating the lower semiconductor chip 210 in a direction from the second protective layer 214 toward the second circuit layer 211, a second backside pad 213 in the second protective layer 214, and a second frontside pad 215 on the second circuit layer 211. In detail, a semiconductor wafer may be provided. The second circuit layer 211 may be formed by forming a transistor or an integrated circuit, etc. on a front surface of the semiconductor wafer, and second frontside pads 215 connected to the second circuit layer 211 may be formed on the second circuit layer 211. After forming through holes on a back surface of the semiconductor wafer, a conductive material may be filled in the through holes to form second vias 212 connected to the second circuit layer 211. A second protective layer 214 covering the second vias 212 may be formed on the back surface of the semiconductor wafer, and second backside pads 213 connected to the second vias 212 may be formed in the second protective layer 214. One surface of the semiconductor wafer on which the second circuit layer 211 is provided may be an active surface, and the opposite surface thereof may be an inactive surface. Thereafter, a sawing process may be performed on the semiconductor wafer along a sawing line so that the lower semiconductor chips 210 may be separated from each other.

The lower semiconductor chip 210 may be bonded to one of the buffer semiconductor chips 100. The lower semiconductor chip 210 and the buffer semiconductor chip 100 may be bonded in a chip-to-wafer form. The lower semiconductor chip 210 may be on the semiconductor wafer 1000. For example, the active surface of the lower semiconductor chip 210 may face the inactive surface of one of the buffer semiconductor chips 100 of the semiconductor wafer 1000. The lower semiconductor chip 210 may be on the buffer semiconductor chip 100 such that the first backside pad 130 of the buffer semiconductor chip 100 and the second frontside pad 215 of the lower semiconductor chip 210 are vertically aligned. In this case, the corner region of the lower semiconductor chip 210 may be on the trench T of the buffer semiconductor chip 100.

A heat treatment process may be performed on the buffer semiconductor chip 100 and the lower semiconductor chip 210. The first backside pad 130 and the second frontside pad 215 may be bonded by the heat treatment process. For example, the first backside pad 130 may be bonded to the second frontside pad 215 to form an integrated body. The bonding of the first backside pad 130 and the second frontside pad 215 may occur naturally. In detail, the first backside pad 130 and the second frontside pad 215 may be composed of the same material (e.g., copper (Cu) or the like), and the first backside pad 130 and the second frontside pad 215 may be bonded by a metal-to-metal hybrid bonding process by surface activation at an interface between the first backside pad 130 and the second frontside pad 215 that are in contact with each other. An insulating pattern of the first protective layer 140 and the second circuit layer 211 may be bonded by the above heat treatment process. In the bonding process of the buffer semiconductor chip 100 and the lower semiconductor chip 210, the lower semiconductor chip 210 may be pressed toward the buffer semiconductor chip 100 for easier bonding. For example, a bonding tool 800 may press the lower semiconductor chip 210 toward the buffer semiconductor chip 100.

In the bonding process of the buffer semiconductor chip 100 and the lower semiconductor chip 210, the lower semiconductor chip 210 and the buffer semiconductor chip 100 may be bent by the heat treatment process applied during the bonding process, and the pressure and stress applied to the buffer semiconductor chip 100 by the lower semiconductor chip 210 may be greatest in the corner region of the lower semiconductor chip 210.

According to some embodiments of the inventive concept, the trench T may be formed in the buffer semiconductor chip 100, and warpage of the buffer semiconductor chip 100 may be suppressed by the trenches T. Accordingly, the buffer semiconductor chip 100 may not be damaged by the pressure and the stress applied by the corner of the lower semiconductor chip 210. That is, a method of manufacturing a semiconductor package with a low occurrence of defects may be provided.

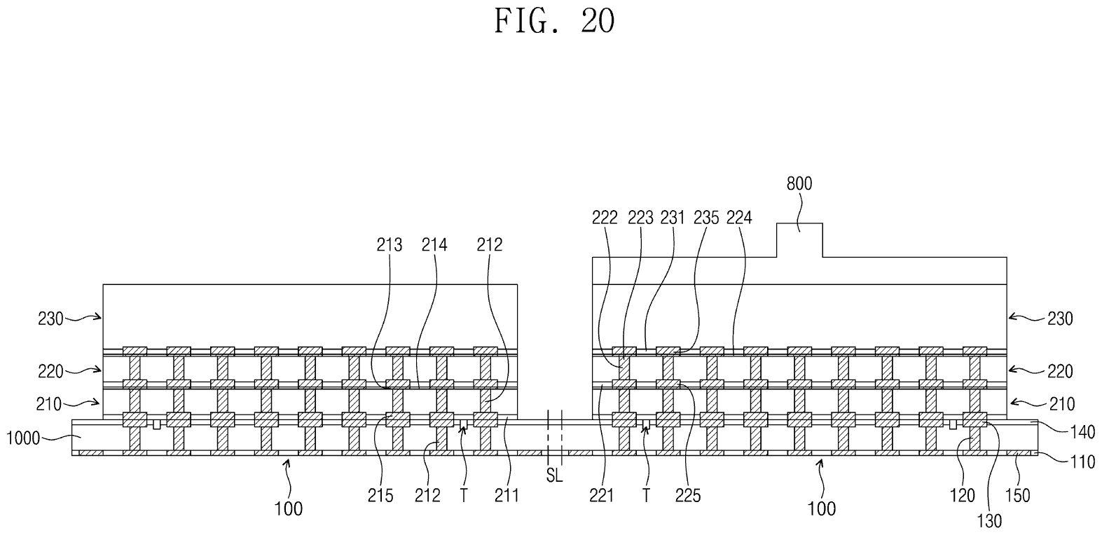

Referring to FIG. 20, an intermediate semiconductor chip 220 and an upper semiconductor chip 230 may be stacked on a lower semiconductor chip 210. For example, the intermediate semiconductor chip 220 may be bonded on an upper surface of the lower semiconductor chip 210, and an upper semiconductor chip 230 may be bonded on an upper surface of the intermediate semiconductor chip 220. The bonding process of the intermediate semiconductor chip 220 and the bonding process of the upper semiconductor chip 230 may be substantially the same as or similar to the bonding process of the lower semiconductor chip 210.

The lower semiconductor chip 210, the intermediate semiconductor chip 220, and the upper semiconductor chip 230 may also be stacked on other buffer semiconductor chips 100 of the semiconductor wafer 1000. As described above, the chip stacks may be formed on the semiconductor wafer 1000.

If necessary, a molding layer surrounding the chip stacks may be formed on the buffer semiconductor chip 100.

Thereafter, a sawing process may be performed on the semiconductor wafer 1000 along the scribe lane region SL so that the semiconductor packages may be separated from each other.

According to the semiconductor package of some embodiments of the inventive concept, the trench may be provided on the upper surface of the buffer semiconductor chip below the corner region of the lower semiconductor chip. The trench may suppress the warpage of the buffer semiconductor chip. Accordingly, the stress applied to the buffer semiconductor chip by the chip stack, particularly the lower semiconductor chip, may be reduced, and the buffer semiconductor chip may be prevented from being damaged by the stress. That is, the semiconductor package with the improved structural stability may be provided, and the method of manufacturing the semiconductor package with the fewer defects may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a substrate including a plurality of vias; and
a chip stack on the substrate, the chip stack comprising a plurality of semiconductor chips, wherein a first semiconductor chip is a lowermost one of the plurality of semiconductor chips in the chip stack,
wherein chip pads of the first semiconductor chip and substrate pads of the substrate are bonded to each other, and the chip pads and the substrate pads are integrally formed of a same metal material,
wherein the first semiconductor chip includes a corner region adjacent to a corner of the first semiconductor chip, and a center region excluding the corner region,
wherein the substrate includes a trench on an upper surface of the substrate, and
wherein the trench extends along a boundary between the corner region and the center region of the first semiconductor chip.

2. The semiconductor package of claim 1, wherein the trench is spaced apart from the corner of the first semiconductor chip.

3. The semiconductor package of claim 2, wherein a distance between the trench and the corner of the first semiconductor chip is 0.1 to 0.25 times a width of the first semiconductor chip.

4. The semiconductor package of claim 2, wherein a distance between the trench and the corner of the first semiconductor chip is 0.1 to 2 millimeters.

5. The semiconductor package of claim 1, wherein the corner of the first semiconductor chip is a corner where a first side surface and a second side surface of the first semiconductor chip intersect, and
wherein the trench extends across the first side surface and the second side surface.

6. The semiconductor package of claim 5, wherein the trench includes one of:
a straight shape crossing the first side surface and the second side surface;
an L-shape having a first portion parallel to the first side surface and a second portion parallel to the second side surface; and
a staircase shape in which portions parallel to the first side surface and portions parallel to the second side surface are alternately connected.

7. The semiconductor package of claim 1, wherein the substrate further includes an alignment key below the corner region of the first semiconductor chip.

8. The semiconductor package of claim 1, wherein a depth of the trench is 0.1 to 0.5 times a thickness of the substrate.

9. The semiconductor package of claim 1, wherein a width of the trench is 0.1 to 0.5 times a distance between two adjacent substrate pads of the substrate pads.

10. The semiconductor package of claim 1, wherein a cross-section of the trench is a square, a triangle, or a semicircle.

11. The semiconductor package of claim 1, wherein the trench is in contact with a side surface of the substrate.

12. The semiconductor package of claim 1, further comprising a buffer structure filling an inside of the trench,
wherein a rigidity of the buffer structure is smaller than a rigidity of the first semiconductor chip, and
wherein an upper surface of the buffer structure is substantially coplanar with the upper surface of the substrate.

13. The semiconductor package of claim 1, wherein a lower surface of the first semiconductor chip is substantially coplanar with a lower surface of one of the chip pads,
wherein the upper surface of the substrate is substantially coplanar with an upper surface of one of the substrate pads, and
wherein the lower surface of the first semiconductor chip is substantially coplanar with the upper surface of the substrate.

14. A semiconductor package comprising:
a buffer semiconductor chip;
a first semiconductor chip on the buffer semiconductor chip, a lower surface of the first semiconductor chip in contact with an upper surface of the buffer semiconductor chip;
a second semiconductor chip on the first semiconductor chip, a lower surface of the second semiconductor chip in contact with an upper surface of the first semiconductor chip; and
a buffer structure between the buffer semiconductor chip and the first semiconductor chip,
wherein the first semiconductor chip has a first side surface and a second side surface in contact with each other, and
wherein the buffer structure extends across the first side surface and the second side surface.

15. The semiconductor package of claim 14, wherein the buffer structure is in an upper portion of the buffer semiconductor chip, and is in contact with a lower surface of the first semiconductor chip.

16. The semiconductor package of claim 14, wherein an upper surface of the buffer structure is substantially coplanar with an upper surface of the buffer semiconductor chip.

17. The semiconductor package of claim 14, wherein the buffer structure includes a metal material, an insulating material, or air.

18. The semiconductor package of claim 14, wherein the buffer semiconductor chip includes a trench on an upper surface of the buffer semiconductor chip, and the buffer structure is in the trench,
wherein the first semiconductor chip includes a corner region adjacent to a corner of the first semiconductor chip, and a center region excluding the corner region, and
wherein the trench extends along a boundary between the corner region and the center region.

19. The semiconductor package of claim 18, wherein a distance between the trench and the corner of the first semiconductor chip is 0.1 to 0.25 times a width of the first semiconductor chip.

20. A semiconductor package comprising:
a semiconductor substrate including a plurality of vias;
a plurality of semiconductor chips stacked on the semiconductor substrate; and
a molding layer on the semiconductor chips on the semiconductor substrate,
wherein the semiconductor substrate further includes:
a trench on an upper surface of the semiconductor substrate; and
a buffer structure in the trench,
wherein the trench extends across a first side surface and a second side surface of a lowermost semiconductor chip of the plurality of the semiconductor chips, a distance between the trench and a corner where the first side surface and the second side surface of the lowermost semiconductor chip intersect is 0.1 to 0.25 times a width of the first semiconductor chip, and
wherein a rigidity of the buffer structure is smaller than a rigidity of the semiconductor substrate.
